(19) United States
(12) Patent Application Publication
(10) Pub. No.: US 2018/0241276 A1
(43) Pub. Date: Aug. 23, 2018

(54) EMP Shielded Generator Housing

(71) Applicant: Walton McCarthy, Fate, TX (US)

(72) Inventor: Walton McCarthy, Fate, TX (US)

(21) Appl. No.: 15/899,614

(22) Filed: Feb. 20, 2018

Related U.S. Application Data
(60) Provisional application No. 62/460,296, filed on Feb. 17, 2017.

(51) Int. Cl. H02K 5/20; H05K 9/00; H02K 11/01; H02K 9/08; H02K 5/02

(52) U.S. Cl. CPC H02K 5/20; H05K 9/0081; H02K 5/02; H02K 11/01; H02K 9/08; H05K 9/0015

(57) ABSTRACT

An EMP-shielded generator enclosure has a vent coupler, a pair of EMP shieldings, an exhaust vent and an inlet vent. The generator enclosure included a generator receptacle and a generator funnel. The generator funnel funnels hot air out of an interior compartment of the generator enclosure and through the exhaust vent. Specifically, the generator funnel is mounted over an upper opening of the generator enclosure. The exhaust vent is attached to the generator funnel by the vent coupler such that the exhaust vent is placed into fluid communication with the interior compartment through the vent coupler. The inlet vent is mounted onto the generator enclosure and enables air to enter the interior compartment. The EMP shieldings are integrated into the inlet vent and the exhaust vent such that electromagnetic radiation is prevented from entering the interior compartment without hindering the flow of air through the interior compartment.

The current application claims a priority to the U.S. Provisional Patent application Ser. No. 62/460,296 filed on Feb. 17, 2017. The current application is filed on Feb. 20, 2018 while Feb. 17, 2018 was on a weekend, and Feb. 19, 2018 was on a national holiday (Presidents day).

### FIELD OF THE INVENTION

The present invention relates generally to enclosures. More particularly, the present invention relates to generator enclosures that prevent the transmission of electromagnetic radiation.

### BACKGROUND OF THE INVENTION

Electromagnetic Pulse (EMP) is created by nuclear weapons detonated at any altitudes above ground. EMP or High Altitude Electromagnetic Pulse (HEMP) damage electrical and electronic circuits by inducing voltages and currents that they are not designed to withstand. EMP induces large voltage and current transients on electrical conductors such as antennas and wires, as well as conductive tracks on electronic circuit boards. When EMP pulses enter a system through a path designed to gather electromagnetic energy, such as an antenna, they are said to have entered through the front door. In contrast, when they enter through an unplanned path, such as cracks, seems, trailing wires or conduits, they have entered through the back door. The efficiency of the energy transfer from pulse to system depends upon the frequency compatibility between the pulse, the entry path, and on the conductivity of the material. In general, sophisticated integrated circuits with short signal paths are susceptible to high frequency pulses while large electrical systems, such as commercial power characterized by long transmission lines, are vulnerable to low frequency EMP. It follows that a broadband EMP weapon threatens a greater number of systems than a narrowband weapon, though the power requirement for a broadband weapon is much higher. Regardless of how EMP enters a system, it damages components simply by overloading them. An electromagnetic pulse is composed of three components:

The first component (E1) is a high frequency (1 mHz-1 gHz) free-field energy pulse with a rise time of a few billionths of a second. This component disrupts or damages electronics-based control systems, sensors, communications systems, computers, and similar devices. (E1) dissipates in air by 50% before reaching the ground but is still very damaging. Conventional surge protectors are not able to react fast enough to provide protection for (E1).

The second component (E2) is a medium frequency pulse, similar to lightning, that follows (E1) by a few millionths of a second. The (E2) component is not particularly dangerous to electronics, especially those hardened against lightning, except when the (E1) pulse damages surge protection circuitry first. An open conductive door on a shelter entranceway, left open to a shelter at the time of an EMP event, will act as a wave guide for EMP into the shelter which is very damaging. Conventional surge protectors are not able to react fast enough to provide protection for (E2).

The third component (E3) is a relatively low frequency (3-30 Hz) slower rising pulse that follows (E2) by a couple thousandths of a second and creates disruptive currents in long transmission lines. The sequence of (E1), (E2), and (E3) is important because each causes damage building on the preceding pulse. (E3) induces a DC current in long conductors above and below ground. A solar storm has this same effect.

An underground steel shelter does not provide adequate EMP shielding. In order for the steel shelter hull to provide EMP shielding, all the POE's or “points of entry” must have a copper or nickel shielded gasket, specifically designed for EMP with a dB rated gasket for the H-Field, E-Field, and Plane Wave. This means that EMP shielded gaskets are needed on hatches at ground level, emergency escapes entranceways connecting to the hull, air inlet ducts, air outlet ducts, electrical lines penetrating the hull, water lines penetrating the hull, antenna wires penetrating the hull, video cables penetrating the hull, etc. In a steel hull, whether made of galvanized culvert or straight wall steel tank, all of the POE's require monthly testing because the hull is constantly corroding unless the underground shelter has a long-term cathodic protection corrosion system. Testing requires very special equipment and personnel. The golden rule for EMP shielding that the military has followed for many years, is “DO NOT USE THE SHELTER HULL AS AN EMP SHIELD AND DO NOT USE THE EMP SHIELD AS A SHELTER. The best approach for EMP protection is to shield each EMP vulnerable item individually inside the shelter because EMP shielded enclosures can be tested and are made of non-corrosive material. Proper EMP shielded enclosures are not made of steel because it is not conductive enough. A proper EMP shielded enclosure is made of aluminum which is 5 times more conductive than steel or copper which is 8.5 times more conductive than steel. Aluminum foil does not shield EMP frequencies. Radios can be disconnected prior to a disaster event but all inverters and chargers, solar charge controllers, solar panels, and most generators need EMP shielded enclosures.

Real EMP protection can only be accomplished if the shielded enclosure meets MIL-STD-188-125-1: “High Altitude Electromagnetic Pulse (HEMP) Protection for Ground-Based C4I Facilities Performing Critical, Time-Urgent Missions Part 1: Fixed Facilities” 17 Jul. 1998. The shelter should be equipped with a Shielded Volume (Shielded Cabinet or enclosure) for the mission essential equipment (MEE) vulnerable to EMP such as the generators, inverters, inverter/chargers, solar charge controllers or anything with a computer used for operations. The EMP shielded enclosure is an aluminum cabinet with some type of door. This cabinet is used for active MEE or radio operation before, during, and after an EMP event. This is necessary for military personnel who are already stationed in the field. This standard requires the radios to be powered in the cabinet, the antennas to be connected to the radios in the cabinet, and the antennas are erected. The shielded cabinet has shielded penetrations for the incoming power and shielded penetrations for antenna cables for three radios, the scanner, HAM, and one spare. Special air blowers are used inside the cabinet to cool the radios. EMP protection is a broad and ambiguous term. To say that a piece of equipment is EMP shielded does not mean that it is shielded completely and for all EMP frequencies, which is what is required to claim a shelter, is EMP shielded.

While small items such as radios, laptops, TVs, CD players etc. can be stored in an aluminum closed box with no vents and EMP gaskets, other items considered as MEE cannot. Diesel generators, inverters, inverter/chargers require an aluminum enclosure with EMP shielded vent, EMP shielded gaskets, and EMP shielded wrap around all cables or hoses penetrating the aluminum enclosure.

Power is critical for life support in above ground or underground structures. Power allows air blowers to operate, supply fresh filtered air, lights to operate so people can read, and function normally. Power allows sewage lift stations to operate and water pumps and radios to operate. Solar panels, composed of multiple diodes are very vulnerable to EMP and shielding them would prevent them from operating. An internal diesel generator EMP shielded to MIL-188-125 is the best and safest way to provide power for underground shelter.

The present design provides for an EMP shielded generator to MIL-188-125 to operate normally inside an underground shelter. To operate in a Nuclear-biological-chemical environment, the air supplied to the generator for cooling and combustion must be filtered to the same standards as breathing air.

### BRIEF DESCRIPTION OF THE DRAWINGS

FIG. 1 is an isometric perspective view of the present invention.

FIG. 2 is a right-side view of the present invention.

FIG. 3 is front sectional view of the present invention taken along line 3-3 in FIG. 2. In this view, the thick dashed line indicates the flow of air through the inlet vent, the interior compartment, and the exhaust vent.

FIG. 4 is an exploded perspective view of the present invention.

FIG. 5 is a block diagram illustrating the electronic connection between the temperature sensor and the ECU used in the present invention.

### DETAIL DESCRIPTIONS OF THE INVENTION

All illustrations of the drawings are for the purpose of describing selected versions of the present invention and are not intended to limit the scope of the present invention.

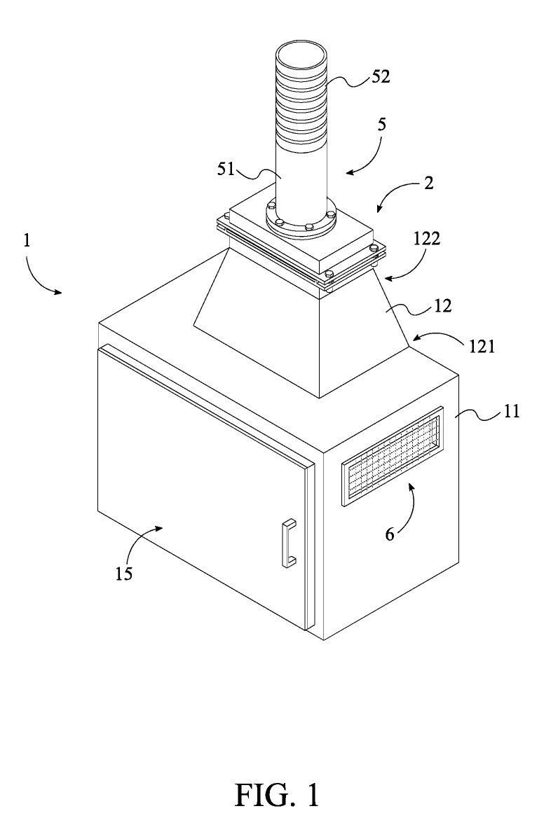

Referring to FIG. 1 through FIG. 5, the preferred embodiment of the present invention, the EMP-shielded generator housing, is a device that prevents a generator from being damaged during an electromagnetic pulse (EMP). To accomplish this, the present invention employs an EMP-shielding enclosure with a dedicated air supply system. The EMP-shielding enclosure prevents EMP energy from damaging the generator while the air supply system circulates air within the enclosure. All the possible points of entry for EMP energy are sealed using EMP-shielding systems including, but not limited to, gaskets, wave guides, and EMP-shielding cable wraps and coatings. As a result, the present invention is enables the generator to operate when the external environment is being bombarded with EMP energy. To achieve this, the present invention comprises a generator enclosure 1, a vent coupler 2, a first EMP shielding 3, a second EMP shielding 4, an exhaust vent 5, and an inlet vent 6. The generator enclosure 1 is a rigid structure that functions as a housing for the generator. Further, the generator enclosure 1 is composed of EMP-shielding materials that prevent the transmission of EMP energy. The generator enclosure 1 is composed of materials including, but not limited to, aluminum, steel, or copper. The first EMP shielding 3 and the second EMP shielding 4 are filtering devices that prohibit the transmission of electromagnetic radiation without inhibiting the flow of fluids or gasses. As a result, the first EMP shielding 3 and the second EMP shielding 4 prevent the exhaust vent 5 and the inlet vent 6 from becoming points of entry for EMP energy.

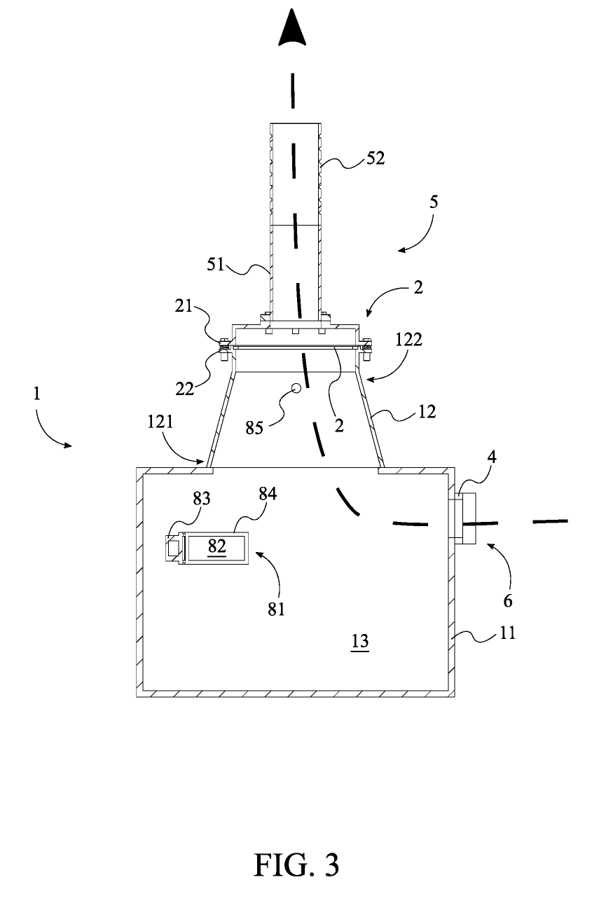

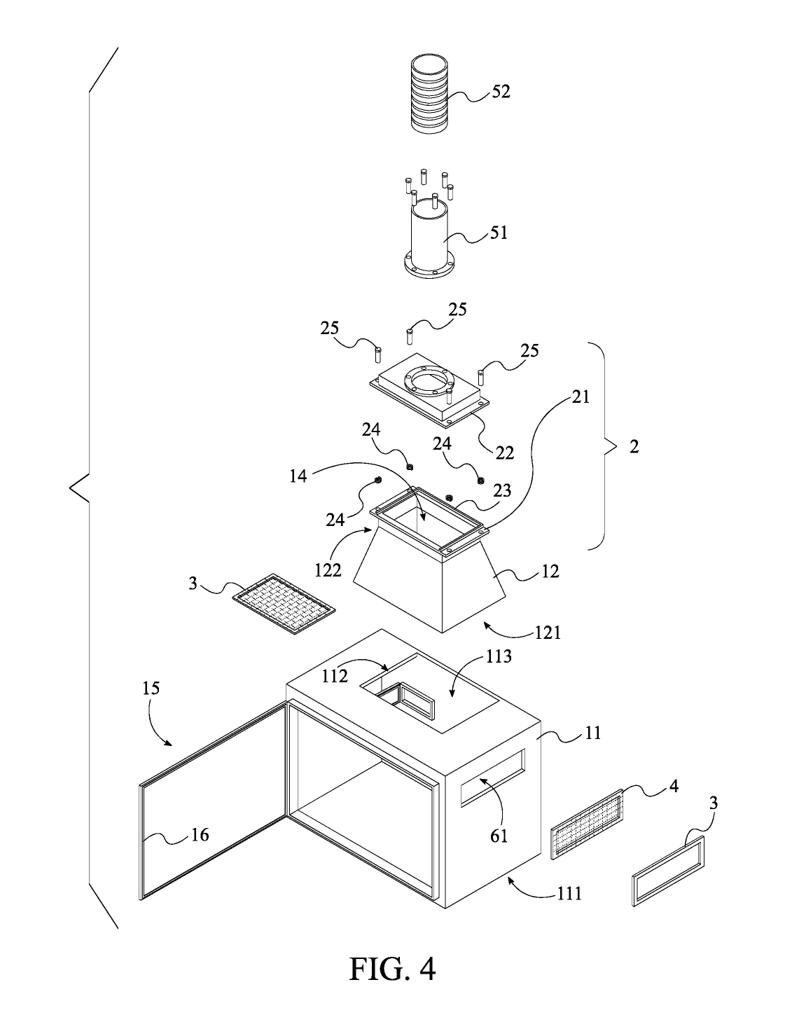

Referring to FIG. 1, FIG. 3, and FIG. 4, because the generator enclosure 1 prevents the transmission of EMP energy the present invention is able to create an enclosed area that isolates electrical and electronic components from ambient electromagnetic radiation. To accomplish this, the generator enclosure 1 comprises a generator receptacle 11, a base 111, an upper rim 112 and a generator funnel 12. The generator receptacle 11 is a container in which the generator is mounted. The upper rim 112 is perimetrically connected around an upper opening of the generator receptacle 11 so that components can be mounted around the upper opening. Additionally, the base 111 is positioned opposite to the upper rim 112, across the generator receptacle 11. Accordingly, the base 111 supports the components of the generator receptacle 11. The generator funnel 12 is a cone-shaped device that is mounted in between the generator receptacle 11 and the vent coupler 2. Specifically, a flared end 121 of the generator funnel 12 is perimetrically mounted around the upper rim 112. Further, an interior cavity of the generator enclosure 1 is delineated by the generator funnel 12 and the generator receptacle 11. Additionally, the vent coupler 2 is adjacently mounted onto a tapered end 122 of the generator funnel 12. As a result, any hot gasses within the interior cavity are funneled toward the vent coupler 2 by the generator funnel 12. The vent coupler 2 is a disengageable fastening mechanism that functions as a mount for the first EMP shielding 3. As such, the first EMP shielding 3 is integrated into the vent coupler 2. Consequently, the first EMP shielding 3 functions as a filter that prevents electromagnetic radiation from traversing through the vent coupler 2 and into the interior compartment 13. The exhaust vent 5 is mounted onto the vent coupler 2, opposite to the tapered end 122 of the generator funnel 12. Consequently, the exhaust vent 5 is retained in a position that facilitates gas exchange with the interior compartment 13. That is, the exhaust vent 5 is in fluid communication with the interior compartment 13 through the first EMP shielding 3 and the vent coupler 2. Accordingly, gasses that exit the interior compartment 13 through the vent coupler 2 must pass through the first EMP shielding 3.

Referring to FIG. 3 and FIG. 4, the exhaust vent 5 and the inlet vent 6 are integral components of the present invention that enable the generator to intake and exhaust gas without being exposed to ambient EMP energy. To achieve this, the present invention further comprises an exhaust hole 14. Additionally, the vent coupler 2 comprises a first connection flange 21 and a second connection flange 22. The exhaust hole 14 traverses into the interior compartment 13 through the tapered end 122 of the generator funnel 12 so that gasses are able to exit the interior compartment 13. Further, the exhaust hole 14 is preferably oriented normal to the tapered end 122. The first connection flange 21 is perimetrically connected around the exhaust hole 14. As a result, half of the vent coupler 2 is attached to the tapered end 122 of the generator enclosure 1. Thus, providing an attachment point for the exhaust vent 5 to be mounted onto the generator enclosure 1. The second connection flange 22 is concentrically aligned to the first connection flange 21. Additionally, the second connection flange 22 is mounted onto the first connection flange 21, opposite to the tapered end 122 of the generator funnel 12. Consequently, the second connection flange 22 can be attached to and detached from the first connection flange 21, when required.

Referring to FIG. 1 and FIG. 4, in the present invention, the second connection flange 22 is preferably mounted around a collection plenum that is a heat resistant material which prevents EMP energy from traversing through the vent coupler 2 and is used to brace the first EMP shielding 3. As such, the vent coupler 2 further comprises a waveguide-receiving receptacle 23. The first EMP shielding 3 is preferably an EMP-shielding waveguide that is mounted within the vent coupler 2. The vent coupler 2 further comprises a waveguide-receiving receptacle 23. The waveguide-receiving receptacle 23 is preferable a three-sided bracket that creates a slot the first EMP shielding 3 is engaged into. Additionally, the waveguide-receiving receptacle 23 is adjacently connected to the first connection flange 21, opposite to the tapered end 122. Further, the waveguide-receiving receptacle 23 is positioned in between the first connection flange 21 and the second connection flange 22. Moreover, the first EMP-shielding is engaged within the waveguide-receiving receptacle 23. As a result, the waveguide-receiving receptacle 23 retains the first EMP shielding 3 in a position that is between the first connection flange 21 and the second connection flange 22. This enables the first EMP shielding 3 to prevent electromagnetic radiation from passing into the interior compartment 13 through the vent coupler 2. Further, this enables the user to remove or replace the first EMP shielding 3 as required.

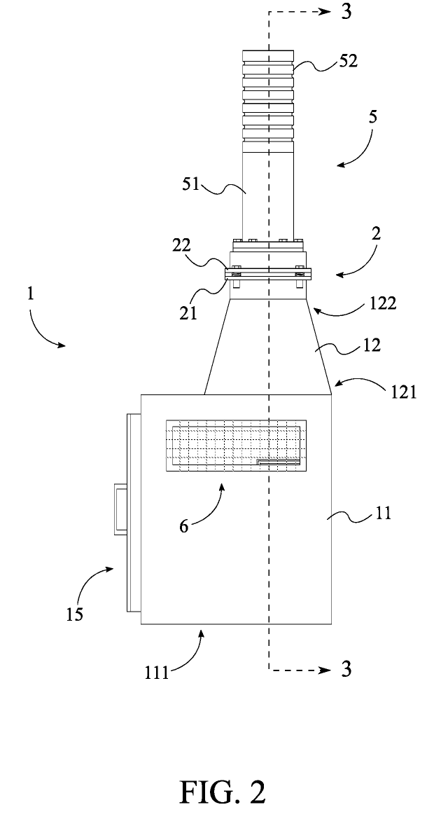

Referring to FIG. 2, FIG. 3, and FIG. 4, the vent coupler 2 is designed to form a quick-release attachment between the exhaust vent 5 and the generator enclosure 1. This enables the user to remove the first EMP shielding 3 by sliding the first EMP shielding 3 out of the waveguide-receiving receptacle 23 when the vent coupler 2 is disengaged. To accomplish this, the vent coupler 2 comprises a plurality of mounting springs 24 and a plurality of mounting bolts 25. The plurality of mounting springs 24 and the plurality of mounting bolts 25 are radially distributed around the exhaust hole 14 so that the vent coupler 2 can form an attachment where tension and compression forces are evenly distributed about the first connection flange 21 and the second connection flange 22. Additionally, the plurality of mounting springs 24 is tensionably connected in between the first connection flange 21 and the second connection flange 22 second flange. Further, the plurality of mounting bolts 25 is connected in between the first connection flange 21 and the second connection flange 22. Moreover, the first connection flange 21 and the second connection flange 22 are pressed against the plurality of mounting springs 24 by the plurality of bolts. As a result, the plurality of mounting springs 24 function as a quick-release mechanism that pushes the second connection flange 22 away from the first connection flange 21 when the plurality of mounting bolts 25 is disengaged from the first connection flange 21 and the second connection flange 22. The vent coupler 2 may further comprises an EMP-shielding gasket. The EMP-shielding gasket is a copper or nickel shielded gasket, specifically designed for EMP with a dB rated gasket for the H-Field, E-Field, and Plane Waves. The EMP-shielding gasket is concentrically aligned to the first connection flange 21. Further, the EMP-shielding gasket is connected in between the first connection flange 21 and the second connection flange 22. Consequently, the EMP shielded gasket provides a redundant level of EMP protection for the vent coupler 2.

Referring to FIG. 3 and FIG. 4, the exhaust vent 5 is the primary point for gasses to exit the generator enclosure 1. To achieve this, the exhaust vent 5 comprises a gas-exchange tube 51. The gas-exchange tube 51 is a hollow tube that acts as the primary conduit through which gasses exiting the interior compartment 13 are moved to a desired location. Additionally, the vent coupler 2 is terminally mounted onto the gas-exchange tube 51. Thus connected, the gas-exchange tube 51 is in fluid communication with the interior compartment 13.

Referring to FIG. 3 and FIG. 4, preferably, the generator is mounted within the interior compartment 13 of the generator enclosure 1 such that the generator exhaust pipe is pointing directly upward centered under the generator funnel 12. Cooling air entering the interior compartment 13 through the inlet vent 6 travels across the generator and up past the generator exhaust pipe extending to approximately 8 inches below the exhaust hole 14. Fresh cooling air entering the inlet vent 6 mixing with warm air from the generator radiator and then past the generator exhaust tube mixes at the top of the generator funnel 12. Moreover, the inlet vent 6 is in fluid communication with exhaust vent 5 through the interior compartment 13 and vent coupler 2.

Referring to FIG. 3 and FIG. 4, the exhaust vent 5 is designed to facilitate the quick-release functionality of the vent coupler 2. To achieve this, the exhaust vent 5 further comprises a section of length-adjustable tubing 52. The section of length adjustable tubing is a hollow pipe that can extend and contract. Embodiments of the section of length-adjustable tubing 52 use devices that include, but are not limited to, telescoping pipes, goosenecks, universal joints, and high temperature flexible tubing. The section of length-adjustable tubing 52 is connected to a second end of the gas-exchange tube 51, opposite to the vent coupler 2. As a result, the section of length-adjustable tubing 52 contracts when the plurality of mounting bolts 25 is removed from the first connection flange 21 and the second connection flange 22. Alternatively, a user may disengage the plurality of fastening guides from the plurality of guide-receiving receptacles. The user is then free to reposition the exhaust vent 5 as desired. The section of length-adjustable tubing 52 is in fluid communication with the interior compartment 13 of the generator housing through the gas-exchange tube 51. Accordingly, the section of length-adjustable tubing 52 does not hinder the flow of gasses through the exhaust vent 5. Further, the section of length-adjustable tubing 52 is designed to act as a dampener for vibrations produced by the generator.

Referring to FIG. 3 and FIG. 4, as described above exhaust vent 5 and the inlet vent 6 enable the generator to intake and exhaust gas without being exposed to ambient EMP energy. To intake air, the present invention further comprises an inlet hole 61. The inlet hole 61 traverses into the interior compartment 13 through the generator receptacle 11 so that gasses, such as fresh air, are able to enter the interior compartment 13. Further, the inlet hole 61 is preferably oriented normal to the lateral surface of the generator enclosure 1. The second EMP shielding 4 is laterally mounted onto the generator receptacle 11, Additionally, the second EMP shielding 4 is positioned over the inlet hole 61 so that gasses, such as fresh air, entering the interior compartment 13 must first pass through the second EMP shielding 4. The inlet vent 6 is adjacently connected to the second EMP shielding 4, opposite to the generator receptacle 11. Further, the inlet vent 6 is in fluid communication with the interior compartment 13 through the second EMP shielding 4 and the inlet hole 61. Accordingly, gasses can be supplied to the interior compartment 13 through the inlet vent 6.

Referring to FIG. 1 and FIG. 4, the present invention enables the user to access the interior compartment 13 of the generator enclosure 1 as desired. To accomplish this, the present invention further comprises a generator-access hatch 15 and a generator hatch gasket 16. The generator-access hatch 15 is laterally integrated into the generator enclosure 1. Additionally, the generator-access hatch 15 traverses into the interior compartment 13. As a result, the generator-access hatch 15 restricts access to the interior compartment 13 of the generator enclosure 1 while in a closed configuration. Conversely, the generator-access hatch 15 permits access to the interior compartment 13 of the generator enclosure 1 while in an open configuration. The generator hatch gasket 16 is composed of an EMP-shielding material. Because the generator-access hatch 15 is a point of entry for EMP energy, the generator-access hatch 15 must be properly sealed. To accomplish this, the EMP-shielding hatch gasket is perimetrically connected around the generator-access hatch 15. Accordingly, EMP energy is prevented from traversing into the interior compartment 13 of the generator enclosure 1 while the generator-access hatch 15 is in the closed configuration.

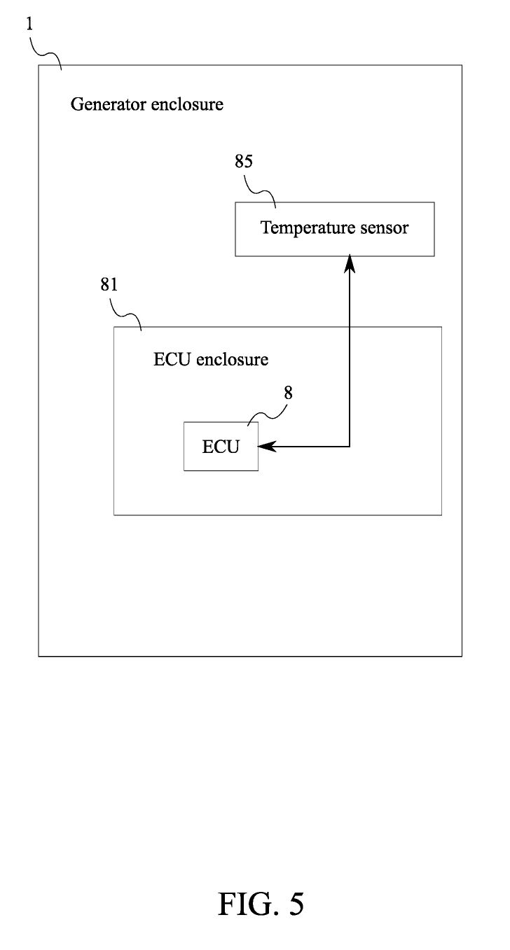

Referring to FIG. 3 and FIG. 5, the present invention is designed to be controlled and monitored by an electronic system. Specifically, the present invention comprises an electronic control unit (ECU) 8 and an ECU enclosure 81. The ECU 8 is a computing device capable of governing the functions of the electronic components housed within the generator enclosure 1. Specifically, the ECU 8 is electronically connected to the generator so that the ECU 8 can monitor and dynamically modify the generator's output. Additionally, the ECU 8 can transmit and receive information to a remotely situated user. The ECU enclosure 81 is an EMP-shielding enclosure that is constructed from materials similar to the generator enclosure 1. Additionally, the ECU enclosure 81 is laterally mounted onto the generator receptacle 11. Further, the ECU 8 is mounted within the ECU compartment 82. As a result, the ECU 8 is housed in an isolated environment that is shielded against any ambient EMP energy. The present invention further comprises an ECU-access hatch 83 and an ECU gasket 84. The ECU-access hatch 83 is the ECU-access hatch 83 is integrated into the ECU enclosure 81. Additionally, the ECU-access hatch 83 traverses into the ECU enclosure 81. As a result, the ECU-access hatch 83 restricts access to the interior compartment 13 of the ECU enclosure 81 while in a closed configuration. Conversely, the ECU-access hatch 83 permits access to the ECU compartment 82 of the ECU enclosure 81 while in an open configuration. The ECU gasket 84 is composed of an EMP-shielding material. Because the ECU-access hatch 83 is a point of entry for EMP energy, the ECU-access hatch 83 must be properly sealed. To accomplish this, the ECU gasket 84 is perimetrically connected around the ECU-access hatch 83. Accordingly, EMP energy is prevented from traversing into the ECU compartment 82 of the ECU enclosure 81 while the ECU-access hatch 83 is in the closed configuration. The system of the present invention further comprises a temperature sensor 85. The temperature sensor 85 is mounted within the interior compartment 13. Additionally, the temperature sensor 85 is thermally coupled to the interior compartment 13. Further, the temperature sensor 85 is electronically connected to the ECU 8. As a result, the ECU 8 is able to monitor the temperature of gasses moving through the interior compartment 13.

Although the invention has been explained in relation to its preferred embodiment, it is to be understood that many other possible modifications and variations can be made without departing from the spirit and scope of the invention as hereinafter claimed.

### Supplemental Descriptions of the Invention

a conventional generator with Tier 4 electronics is contained in an aluminum generator enclosure. The generator enclosure is located in a positive pressure room where filtered air is pumped into the room and the only way to relieve the pressure is for the air to exit through EMP shielded air vent. The air then travels up through generator exhaust funnel taking with it exhaust gases, then cooling air, exhaust gases pass through an EMP Shielded Vent, and then out to the ground surface through air duct.

The generator has a rotating fan blade pushing the air through the radiator and out from the radiator on the opposite side as hot air which rises to enter generator funnel. Air forced up through the generator funnel creates negative pressure drawing up the air and exhaust gases and from the generator.

The present invention includes a quick change EMP vent design that allows the collection plenum above the EMP vent to be raised by springs when bolts are loosened to allow the EMP shielded vent to slide out. The collection plenum is allowed to raise due to the high temperature flex tube connected to the ceiling of the shelter. The vent is then cleaned and replaced. The top of generator funnel has a flat flange mating with, and in communication with, the flat flange on collection plenum that are bolted together through spring to form an air tight seal around EMP vent. The EMP shielded air vent is slid into place guided by guides that surround the EMP shielded vent on three sides. An NPTF coupling is located on generator funnel to accept a temperature gage to monitor the temperature of the gases leaving the enclosure.

The generator housing cover will be hinged and clamped to the generator face through gasket which is glued onto perimeter flange. In order to start the generator, the generator cover is opened allowing access to the key switch, to start the generator. The generator and batter bank are monitored by an electronic panel located and shielded in which has a cover and EMP shielded gasket. The weight of the cover compresses the EMP shielded gasket shielding the electronic panel.

What is claimed is:

1. An EMP-shielded generator housing comprises:
a generator enclosure;
a vent coupler;
a first EMP shielding;
a second EMP shielding;
an exhaust vent;
inlet vent;
the generator enclosure comprises a generator receptacle, a base, an upper rim, and a generator funnel;
the upper rim being perimetrically connected around an upper opening of the generator receptacle;
the base being positioned opposite to the upper rim, across the generator receptacle;
a flared end of the generator funnel being perimetrically mounted around the upper rim;
an interior compartment of the generator enclosure being delineated by the generator funnel and the generator receptacle;
the vent coupler being adjacently mounted onto a tapered end of the generator funnel;
the first EMP shielding being integrated into the vent coupler;
the exhaust vent being mounted onto the vent coupler, opposite to the tapered end of the generator funnel;
the exhaust vent being in fluid communication with the interior compartment through the first EMP-shielding and the vent coupler;
the inlet vent being laterally mounted onto the generator receptacle;
the second EMP shielding being integrated into the inlet vent; and
the inlet vent being in fluid communication with the interior compartment though the second EMP shielding.

2. The EMP-shielded generator housing as claimed in claim 1 comprises:
an exhaust hole;
the vent coupler comprises a first connection flange a second connection flange;
the exhaust hole traversing into the interior compartment through the tapered end of the generator funnel;
the first connection flange being perimetrically connected around the exhaust hole;
the second connection flange being concentrically aligned to the first connection flange; and
the second connection flange being mounted onto the first connection flange, opposite to the tapered end of the generator funnel.

3. The EMP-shielded generator housing as claimed in claim 2 comprises:
the first EMP-shielding being an EMP-shielding wave guide;
the vent coupler further comprises a waveguide-receiving receptacle;
the waveguide-receiving receptacle being adjacently connected to the first connection flange, opposite to the tapered end;
the waveguide-receiving receptacle being positioned in between the first connection flange and the second connection flange; and
the first EMP-shielding being engaged within the waveguide-receiving receptacle.

4. The EMP-shielded generator housing as claimed in claim 2 comprises:
the vent coupler further comprises a plurality of mounting springs and a plurality of mounting bolts;
the plurality of mounting springs and the plurality of mounting bolts being radially distributed around the exhaust hole;
the plurality of mounting springs being tensionably connected in between the first connection flange and the second connection flange second flange;
the plurality of mounting bolts being connected in between the first connection flange and the second connection flange; and
the first connection flange and the second connection flange being pressed against the plurality of mounting springs by the plurality of bolts.

5. The EMP-shielded generator housing as claimed in claim 1 comprises:
the exhaust vent comprises a gas-exchange tube;
the vent couplet being terminally mounted onto the gas-exchange tube; and
the gas-exchange tube being in fluid communication with the interior compartment of the of the generator enclosure through the vent coupler.

6. The EMP-shielded generator housing as claimed in claim 5 comprises:
the exhaust vent further comprises a section of length-adjustable tubing;
the section of length-adjustable tubing being terminally connected to the gas-exchange tube, opposite to the vent coupler; and
the section of length-adjustable tubing being in fluid communication with the interior compartment of the generator housing through the gas-exchange tube.

7. The EMP-shielded generator housing as claimed in claim 2 comprises:
an inlet hole;
the second EMP-shielding being an EMP-shielding wave guide;
the inlet hole traversing through the generator receptacle into the interior compartment;
the second EMP shielding being laterally mounted onto the generator receptacle;
the second EMP shielding being positioned over the inlet hole;
the inlet vent being adjacently connected to the second EMP shielding, opposite to the generator receptacle; and
the inlet vent being in fluid communication with the interior compartment through the second EMP shielding and the inlet hole.

8. The EMP-shielded generator housing as claimed in claim 1 comprises:
a generator-access hatch;
a generator hatch gasket;
the generator-access hatch being laterally integrated into the generator enclosure;
the generator-access hatch traversing into the interior compartment; and
the EMP-shielding hatch gasket being perimetrically connected around the generator-access hatch.

9. The EMP-shielded generator housing as claimed in claim 1 comprises:
a generator;
an electronic control unit (ECU);
an ECU enclosure;
the generator being mounted within the ECU compartment;
the ECU enclosure being mounted within the interior compartment the generator receptacle;
the ECU being mounted within the ECU compartment; and
the ECU being electronically connected to the generator.

10. The EMP-shielded generator housing as claimed in claim 9 comprises:
an ECU-access hatch
an ECU gasket;
the ECU-access hatch being integrated into the ECU enclosure;
the ECU-access hatch traversing into the ECU enclosure; and
the ECU gasket being perimetrically connected around the ECU-access hatch.

11. The EMP-shielded generator housing as claimed in claim 9 comprises:
a temperature sensor;
the temperature sensor being mounted within the interior compartment;
the temperature sensor being thermally coupled to the interior compartment; and
the temperature sensor being electronically connected to the ECU.

12. An EMP-shielded generator housing comprises:
a generator enclosure;
a vent coupler;
a first EMP shielding;
a second EMP shielding;
an exhaust vent;
inlet vent;
an exhaust hole;
a generator;
an electronic control unit (ECU);
an ECU enclosure;
the generator enclosure comprises a generator receptacle, a base, an upper rim, and a generator funnel;
the vent coupler comprises a first connection flange a second connection flange;
the exhaust vent comprises a gas-exchange tube;
the upper rim being perimetrically connected around an upper opening of the generator receptacle;
the base being positioned opposite to the upper rim, across the generator receptacle;
a flared end of the generator funnel being perimetrically mounted around the upper rim;
an interior compartment of the generator enclosure being delineated by the generator funnel and the generator receptacle;
the vent coupler being adjacently mounted onto a tapered end of the generator funnel;
the first EMP shielding being integrated into the vent coupler;
the exhaust vent being mounted onto the vent coupler, opposite to the tapered end of the generator funnel;
the exhaust vent being in fluid communication with the interior compartment through the first EMP-shielding and the vent coupler;
the inlet vent being laterally mounted onto the generator receptacle;
the second EMP shielding being integrated into the inlet vent;
the inlet vent being in fluid communication with the interior compartment though the second EMP shielding;
the exhaust hole traversing into the interior compartment through the tapered end of the generator funnel;
the first connection flange being perimetrically connected around the exhaust hole;
the second connection flange being concentrically aligned to the first connection flange;
the second connection flange being mounted onto the first connection flange, opposite to the tapered end of the generator funnel;
the vent couplet being terminally mounted onto the gas-exchange tube;
the gas-exchange tube being in fluid communication with the interior compartment of the of the generator enclosure through the vent coupler;
the generator being mounted within the ECU compartment;
the ECU enclosure being mounted within the interior compartment the generator receptacle;
the ECU being mounted within the ECU compartment; and
the ECU being electronically connected to the generator.

13. The EMP-shielded generator housing as claimed in claim 12 comprises:
the first EMP-shielding being an EMP-shielding wave guide;
the vent coupler further comprises a waveguide-receiving receptacle;
the waveguide-receiving receptacle being adjacently connected to the first connection flange, opposite to the tapered end;
the waveguide-receiving receptacle being positioned in between the first connection flange and the second connection flange; and
the first EMP-shielding being engaged within the waveguide-receiving receptacle.

14. The EMP-shielded generator housing as claimed in claim 12 comprises:
the vent coupler further comprises a plurality of mounting springs and a plurality of mounting bolts;
the plurality of mounting springs and the plurality of mounting bolts being radially distributed around the exhaust hole;
the plurality of mounting springs being tensionably connected in between the first connection flange and the second connection flange second flange;
the plurality of mounting bolts being connected in between the first connection flange and the second connection flange; and
the first connection flange and the second connection flange being pressed against the plurality of mounting springs by the plurality of bolts.

15. The EMP-shielded generator housing as claimed in claim 12 comprises:
the exhaust vent further comprises a section of length-adjustable tubing;
the section of length-adjustable tubing being terminally connected to the gas-exchange tube, opposite to the vent coupler; and
the section of length-adjustable tubing being in fluid communication with the interior compartment of the generator housing through the gas-exchange tube.

16. The EMP-shielded generator housing as claimed in claim 12 comprises:
an inlet hole;
the second EMP-shielding being an EMP-shielding wave guide;
the inlet hole traversing through the generator receptacle into the interior compartment;
the second EMP shielding being laterally mounted onto the generator receptacle;
the second EMP shielding being positioned over the inlet hole;
the inlet vent being adjacently connected to the second EMP shielding, opposite to the generator receptacle; and
the inlet vent being in fluid communication with the interior compartment through the second EMP shielding and the inlet hole.

17. The EMP-shielded generator housing as claimed in claim 12 comprises:
a generator-access hatch;
a generator hatch gasket;
the generator-access hatch being laterally integrated into the generator enclosure;
the generator-access hatch traversing into the interior compartment; and
the EMP-shielding hatch gasket being perimetrically connected around the generator-access hatch.

18. The EMP-shielded generator housing as claimed in claim 12 comprises:
an ECU-access hatch
an ECU gasket;
the ECU-access hatch being integrated into the ECU enclosure;
the ECU-access hatch traversing into the ECU enclosure; and
the ECU gasket being perimetrically connected around the ECU-access hatch.

19. The EMP-shielded generator housing as claimed in claim 12 comprises:
a temperature sensor;
the temperature sensor being mounted within the interior compartment;
the temperature sensor being thermally coupled to the interior compartment; and
the temperature sensor being electronically connected to the ECU.
